(19) United States
(12) Patent Application Publication
(10) Pub. No.: US 2025/0224457 A1
(43) Pub. Date: Jul. 10, 2025

(54) METHOD AND SYSTEM WITH ELECTRONIC DEVICE BATTERY PERFORMANCE DETERMINATION

(71) Applicant: Samsung Electronics Co., Ltd., Suwon-si (KR)

(72) Inventors: Sagar Bharathraj, Bengaluru (IN); Myeongjae Lee, Suwon-si (KR); Shashishekara Parampalli Adiga, Bengaluru (IN)

(73) Assignee: Samsung Electronics Co., Ltd., Suwon-si (KR)

(21) Appl. No.: 19/013,658

(22) Filed: Jan. 8, 2025

(30) Foreign Application Priority Data
Jan. 8, 2024 (IN) 202441001515
Oct. 14, 2024 (KR) 10-2024-0139539

(51) Int. Cl. G01R 31/392; G01R 31/3828; G01R 31/389; G01R 31/52

(52) U.S. Cl. CPC G01R 31/392; G01R 31/3828; G01R 31/389; G01R 31/52

(57) ABSTRACT

A processor-implemented method including determining a plurality of zones associated with a current charging profile of a battery of an electronic device by utilizing a multi-stage constant-current constant voltage (MSCC-CV) charging protocol, segregating the determined plurality of zones into a first zone, a second zone, and a third zone, based on a preset criterion, and determining, based on information associated with one or more of the first zone, the second zone, and the third zone, one or more of an end of life (EOL) of the battery, a short circuit of the battery, and a state of health (SOH) of the battery to determine performance of the battery.

### CROSS-REFERENCE TO RELATED APPLICATIONS

This application claims the benefit under 35 USC § 119(a) of Indian Patent Application number 202441001515 filed on Jan. 8, 2024, in the Indian Patent Office, and Korean Patent Application No. 10-2024-0139539 filed on Oct. 14, 2024, in the Korean Intellectual Property Office, the entire disclosures of which are incorporated by reference herein for all purposes.

### BACKGROUND

### 1. Field

The following description relates to a method and system with electronic device battery performance determination.

### 2. Description of Related Art

Battery technology is closely associated with the efficiency and functionality of mobile phones, electric vehicles (EVs), and information technology (IT) applications. For example, lithium-ion batteries are extensively employed in mobile phones and EVs owing to their high energy density and extended cycle life. To ensure safe and efficient functioning in the field of battery technology, a number of critical parameters may have to be monitored. Examples of the critical parameters may include, but are not limited to, a temperature, a voltage, a current, a state of charge (SOC), a state of health (SOH), and an end of life (EOL). Careful monitoring of these critical parameters may predict battery performance, prevent overcharging or over-discharging, and ensure overall safety.

Some typical methods have explored the use of a battery management system (BMS) for monitoring battery parameters (critical parameters). The BMS is an electronic system that administers and supervises the charging and discharging of rechargeable batteries. The BMS may be configured to collect data on battery parameters, conduct computations, and provide real-time information on battery states. For example, in the context of EVs and electronic devices, the BMS may play a pivotal role in monitoring the temperature, voltage, and current of a battery pack to optimize performance and ensure safety. Furthermore, other typical methods have also explored the use of one or more intelligent mechanisms and machine learning (ML) models to analyze battery data, predict performance, and identify anomalies. However, as discussed below, typical ML models encounter the following issues.

Firstly, the early detection of battery health and EOL is desired. This may include identifying faults such as short circuits, especially at an early stage. Additionally, Li-Ion battery-powered electronic devices may typically include determining a classification of identified short circuits as one of a “soft” or “hard” short circuit. A “soft” short circuit may occur due to a temporary fault, such as a momentary contact between conductive materials, resulting in a brief disruption of a current flow. On the other hand, a “hard” short circuit may include a more serious and persistent fault, such as physical damage in a battery insulator, leading to a persistent and potentially damaging flow of current. Moreover, the estimation of a short resistance, especially at the early stage, for Li-Ion battery-powered electronic devices is also typically desired. Furthermore, it is typically desirable to proactively predict the EOL of the battery, which occurs when the lifespan of the battery reaches 80% of the rated capacity. This proactive approach enables the implementation of pre-emptive measures aimed at extending the lifespan of the battery, a task that typical methods have been unable to achieve. For example, a failure to proactively predict and estimate short circuits with a resistance of 500Ω or more may lead to battery damage or catastrophic events, such as fires. Thus, an early prediction and estimation of short circuits, which is a capability that typical methods lack, may prevent these catastrophic events.

Secondly, typical battery analysis methods are impractical for device implementation and may only predict late-stage short circuits (e.g., 100Ω or less) with less than, for example, 85% accuracy. Additionally, these typical ML-based battery analysis methods rely on extensive training data, intricate computations, and specialized probes for detecting and predicting the EOL of the battery, making them impractical for on-device implementation. For example, such a scenario may be considered in a portable medical device using a high-capacity battery-powered electronic device. The typical battery analysis methods require large amounts of historical data and complex algorithms to analyze the SOH of the battery and predict the EOL of the battery. Additionally, specialized probes are needed to gather detailed information about the internal condition of the battery. As a result, implementing these methods directly on medical devices becomes unfeasible due to the computational and hardware requirements.

Thus, it is desired to address the above-mentioned shortcomings of typical battery analysis or other issues or at least provide useful alternatives for enhancing the battery performance of an electronic device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including determining a plurality of zones associated with a current charging profile of a battery of an electronic device by utilizing a multi-stage constant-current constant voltage (MSCC-CV) charging protocol, segregating the determined plurality of zones into a first zone, a second zone, and a third zone, based on a preset criterion, and determining, based on information associated with one or more of the first zone, the second zone, and the third zone, one or more of an end of life (EOL) of the battery, a short circuit of the battery, and a state of health (SOH) of the battery to determine performance of the battery.

The first zone may include a high current-low state of charge (SOC), the second zone may include a mid-current-mid SOC, and the third zone may include a low current-high SOC.

The determining of the EOL of the battery may include determining a charge capacity in the first zone and determining the EOL of the battery at an early stage of a charging cycle of the battery, based on a result of the determination of the charge capacity.

The determining of the short circuit of the battery may include determining a first charge capacity in the first zone, determining a third charge capacity in the third zone, determining a relative ratio between the first charge capacity and the third charge capacity, determining a short resistance based on the determined relative ratio, and classifying the determined short resistance as a soft short resistance or a hard short resistance based on a preset threshold value.

The method may include, in response to the determined short resistance being classified as the hard short resistance, providing an indication of the hard short to a user of the electronic device.

The determining of the SOH of the battery may include determining a first charge capacity in the first zone, determining a third charge capacity in the third zone, determining a sum of the charge capacities of the first charge capacity and the third charge capacity, and determining a charge capacity of the battery at an early stage of a charging cycle of the battery, based on a result of the determined sum.

The current charging profile of the battery may include current zone data and a state of charge (SOC) zone.

In a general aspect, here is provided a non-transitory computer-readable storage medium storing instructions that, when executed by a processor, cause the processor to perform the method.

In a general aspect, here is provided a system including processors configured to execute instructions and a memory storing the instructions, and an execution of the instructions configures the processors to determine a plurality of zones associated with a current charging profile of a battery associated with the system by utilizing a multi-stage constant-current constant voltage (MSCC-CV) charging protocol, segregate the determined plurality of zones into a first zone, a second zone, and a third zone, based on a preset criterion, and determine, based on information associated with one or more of the first zone, the second zone, and the third zone, one or more of an end of life (EOL) of the battery, a short circuit of the battery, and a state of health (SOH) of the battery to determine performance of the battery.

The first zone may include a high current-low state of charge (SOC), the second zone may include a mid-current-mid SOC, and the third zone may include a low current-high SOC.

To determine the EOL of the battery, the processors may be configured to determine a charge capacity in the first zone and determine the EOL of the battery at an early stage of a charging cycle of the battery, based on a result of the determination of the charge capacity.

To determine the short circuit of the battery, the processors are configured to determine a first charge capacity in the first zone, determine a third charge capacity in the third zone, determine a relative ratio between the first charge capacity and the third charge capacity, and determine a presence of a soft short resistance or a hard short resistance based on the relative ratio compared to a preset threshold value.

The processors may be configured to, in response to the determined short resistance being classified as the hard short resistance, notifying a user of the system to perform an action to enhance the performance of the battery.

The determination of the SOH of the battery may include determining a first charge capacity in the first zone, determining a third charge capacity in the third zone, determining a sum of the charge capacities of the first charge capacity and the third charge capacity, and determining a charge capacity of the battery at an early stage of a charging cycle of the battery, based on a result of the determined sum.

A current charging profile of the battery may include current zone data and a state of charge (SOC) zone.

In a general aspect, here is provided an electronic device including processors configured to execute instructions and a memory storing the instructions, and an execution of the instructions configures the processors to determine a first zone and a plurality of other zones associated with a current charging profile of a battery by utilizing a multi-stage constant-current constant voltage (MSCC-CV) charging protocol based on a preset criterion and determine, based on information associated with the first zone and the plurality of other zones, a battery performance of the battery at an early stage of a charging cycle of the battery.

The battery performance includes one or more of an end of life (EOL) of the battery, a short circuit of the battery, and a state of health (SOH) of the battery.

The determining of the battery performance may include determining a charge capacity in the first zone and determining an end of life (EOL) of the battery based on a result of the determination of the charge capacity.

The determining of battery performance may include determining a first charge capacity in the first zone, determining a final charge capacity in a final zone of the plurality of other zones, and determining whether a hard short or a soft short has occurred within the battery based a relative ratio between the first charge capacity and the final charge capacity being compared against a preset threshold value.

Other features and aspects will be apparent from the following detailed description, the drawings, and the claims.

### BRIEF DESCRIPTION OF THE DRAWINGS

FIG. 1 illustrates an example electronic device for determining battery performance at an early stage of a charging cycle of a battery according to one or more embodiments.

FIG. 2 illustrates an example method of determining battery performance in an electronic device according to one or more embodiments.

FIG. 3 illustrates an example chart in which an electronic device segregates a plurality of zones into a first zone, a second zone, and a third zone, based on at least one of a predefined criterion or a predefined threshold value according to one or more embodiments.

FIG. 4 illustrates an example method of determining an end of life (EOL) of a battery of an electronic device at an early stage of a charging cycle of a battery according to one or more embodiments.

FIG. 5 illustrates an example chart in which an electronic device determines an EOL of a battery at an early stage of a charging cycle of battery according to one or more embodiments.

FIG. 6 illustrates an example method of determining a short circuit of a battery of an electronic device at an early stage of an electronic device according to one or more embodiments.

FIGS. 7A and 7B illustrate example charts in which an electronic device determines a short circuit of a battery at an early stage of a charging cycle of the battery according to one or more embodiments.

FIG. 8 illustrates an example method of determining a state of health (SOH) of a battery of an electronic device at an early stage of a charging cycle of the battery according to one or more embodiments.

FIG. 9 illustrates an example chart in which an electronic device determines an SOH of a battery at an early state of a charging cycle of the battery according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

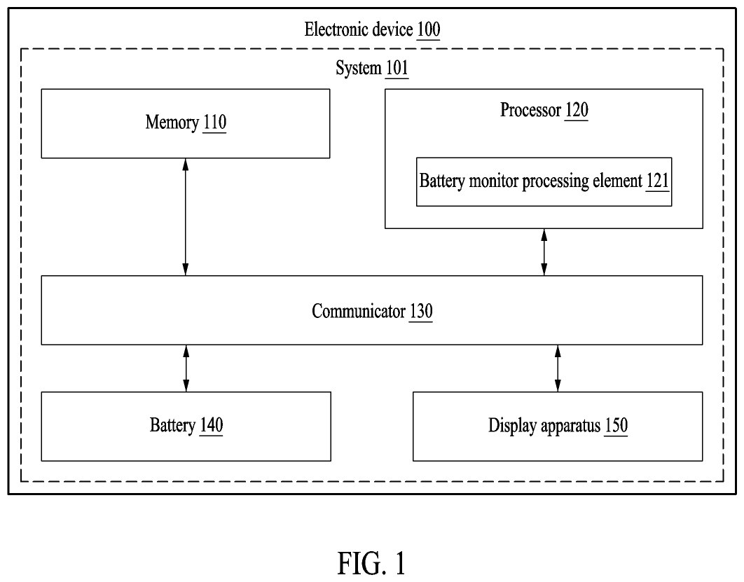

FIG. 1 illustrates an example electronic device for determining battery performance at an early stage of a charging cycle of a battery according to one or more embodiments.

Referring to FIG. 1, in a non-limiting example, an electronic device 100 may include a system 101. The system 101 may include a memory 110, a processor 120, a communicator 130, a battery 140, and a display apparatus 150. In an example, the system 101 may be implemented by one or more electronic devices not illustrated in FIG. 1.

Examples of the electronic device 100 may include, but are not limited to, a smartphone, a tablet computer, a personal digital assistant (PDA), an internet of things (IoT) device, a wearable device, and an electric vehicle (EV).

In an example, the memory 110 may store instructions to be executed by the processor 120 for determining the battery performance of the electronic device 100. The memory 110 may include a non-volatile storage element. Examples of the non-volatile storage element may include a magnetic hard disc, an optical disc, a floppy disc, flash memory, or electrically programmable memory (EPROM) or electrically erasable and programmable memory (EEPROM). In addition, the memory 110 may, in some examples, be considered a non-transitory storage medium. The term “non-transitory” may indicate that the storage medium is not embodied in a propagated signal or a carrier wave. However, the term “non-transitory” should not be interpreted that the memory 110 is non-movable. In some examples, the memory 110 may be configured to store larger amounts of information than the memory. In particular examples, a non-transitory storage medium may store data (e.g., random-access memory (RAM) or cache) that may change over time. The memory 110 may be an internal storage device of the electronic device 100 and may be an external storage device, a cloud storage, or any other type of external storage device.

The processor 120 may communicate with the memory 110, the communicator 130, the battery 140, and the display apparatus 150. The processor 120 may be configured to execute instructions stored in the memory 110 and perform various processes for determining the battery performance of the electronic device 100. The processor 120 may be configured to execute programs or applications to configure the processor 120 to control the electronic device 100, or system 101, to perform one or more or all operations and/or methods involving the reconstruction of images, and may include any one or a combination of two or more of, for example, a central processing unit (CPU), an application processor (AP), or the like, a graphics-dedicated processing unit such as a graphics processing unit (GPU), a visual processing unit (VPU), and an artificial intelligence (AI)-dedicated processor such as a neural processing unit (NPU).

The processor 120 may be implemented through a processing circuit such as a logic gate, an integrated circuit, a microprocessor, a microcontroller, a memory circuit, a passive electronic component, an active electronic component, an optical component, a fixed circuit, or the like, and may optionally be driven by firmware. These circuits may, for example, be embodied in one or more semiconductor chips or on substrate supports such as a printed circuit board and the like. The processor 120 may include processing elements and may be include one or more processors.

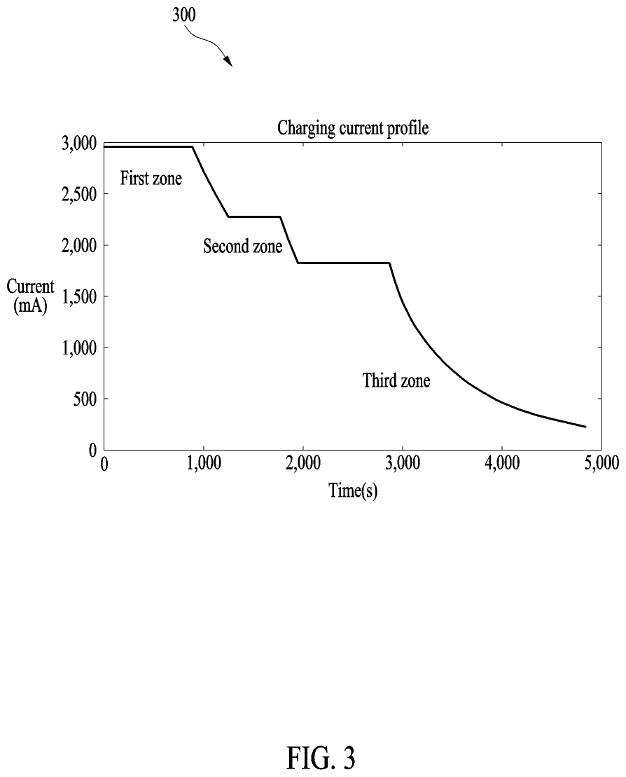

The processor 120 may include a battery monitor processing element 121. The battery monitor processing element 121 may determine a plurality of zones associated with a current charging profile of the battery 140 of the electronic device 100 by utilizing a multi-stage constant-current constant voltage (MSCC-CV) charging protocol, as described in greater detail below with respect to FIG. 3. In addition, the battery monitor processing element 121 may segregate the plurality of determined zones into a first zone Z1, a second zone Z2, and a third zone Z3, based on one or more of a preset criterion or a preset threshold value, as described with reference to FIG. 3.

In an example, in a scenario in which a smartphone is being charged, the battery monitor processing element 121 may employ the MSCC-CV charging protocol to analyze the current charging profile of the battery 140 and identify various charging zones, based on a state of charge (SOC) and a voltage level of the battery 140. This allows the electronic device 100 to optimize a charging process and ensure efficient and safe battery charging.

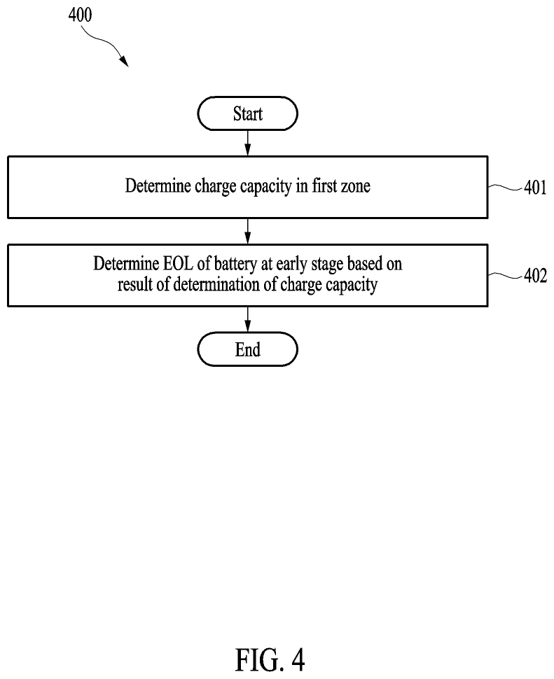

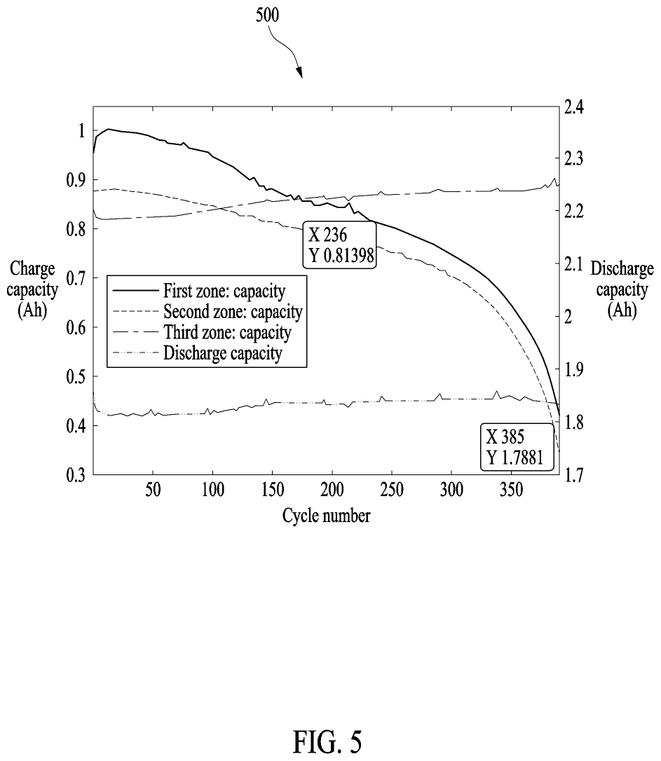

The battery monitor processing element 121 may determine an end of life (EOL) of the battery 140 at an early stage (e.g., before at least 40% of the total cycle life) of a charging cycle of the battery 140, based on information related to at least one of the first zone, the second zone, and the third zone, as described in greater detail below with respect to FIGS. 4 and 5.

In an example, in a scenario involving an EV, the battery monitor processing element 121 may utilize information received from the various charging zones to analyze the degradation of the battery over time. By monitoring a charge capacity, a discharge capacity, and a voltage characteristic in each zone, the battery monitor processing element 121 may accurately determine the EOL of the battery 140 and provide an advanced warning to a vehicle system, enabling proactive maintenance and replacement planning.

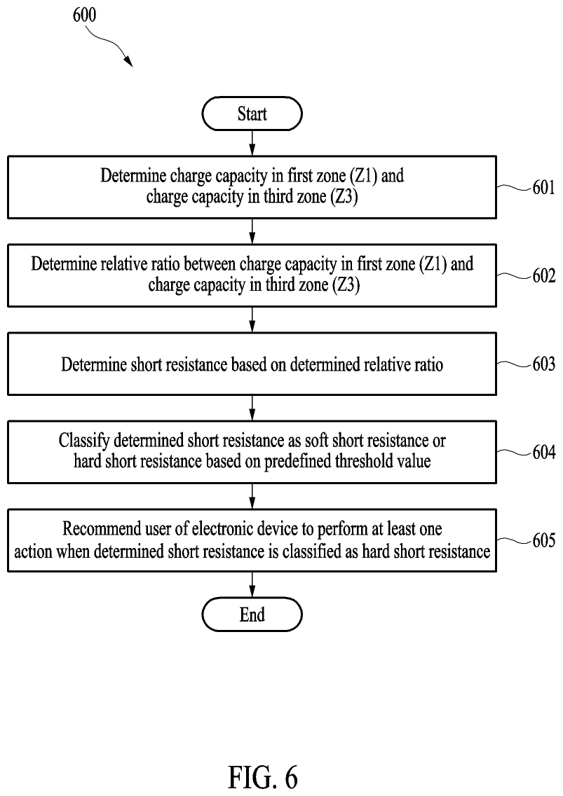

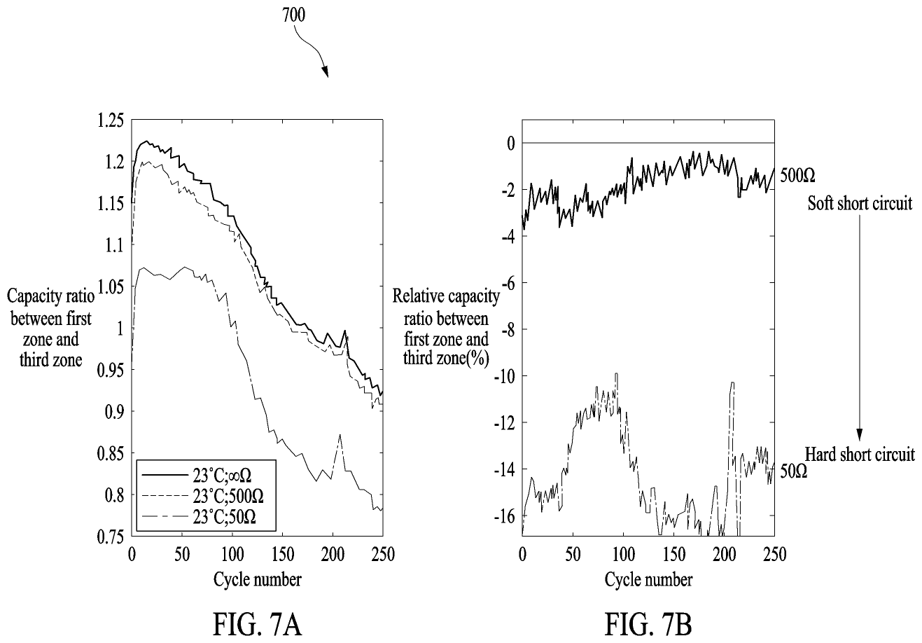

The battery monitor processing element 121 may determine a short circuit of the battery 140 at the early stage (e.g., as early as 500 Ohms (Ω)) of the charging cycle of the battery 140, based on information related to at least one of the first zone, the second zone, and the third zone, as described in greater detail below with respect to FIGS. 6 and 7.

In an example, in the context of EV charging, the battery monitor processing element 121 may utilize information received from multiple charging zones to monitor a voltage difference and a current flow pattern. By analyzing these parameters across multiple charging zones, the battery monitor processing element 121 may identify a potential short circuit that may occur within the battery 140. In another scenario, involving a portable electronic device, the battery monitor processing element 121 may leverage data from multiple charging zones to detect abnormal voltage spikes or current surges that may indicate a short circuit state. This capability may enable the early detection and mitigation of a short circuit event, enhancing the safety and reliability of a battery-powered electronic device.

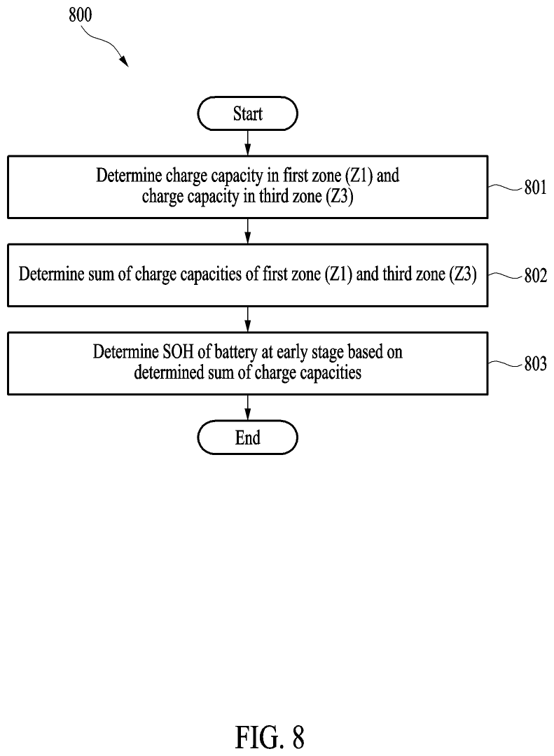

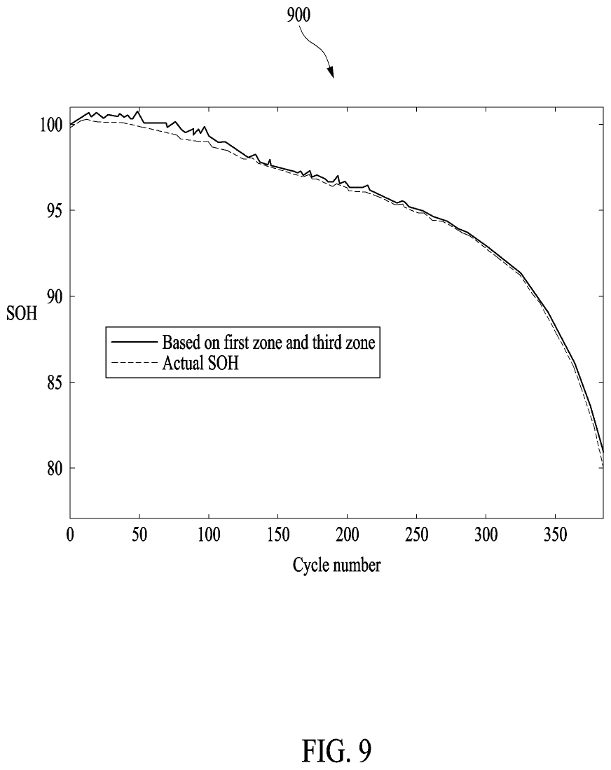

The battery monitor processing element 121 may determine a state of health (SOH) of the battery 140 at the early stage of the charging cycle of the battery 140, based on information related to at least one of the first zone, the second zone, and the third zone, as described in greater detail below with respect to FIGS. 8 and 9.

In an example, in the context of EV charging, the battery monitor processing element 121 may utilize information received from various charging zones to analyze the performance and SOH of the battery at the beginning of a charging process. By monitoring factors such as charging rate, temperature, and voltage level across multiple zones, the battery monitor processing element 121 may accurately evaluate the SOH of the battery and detect an early sign of degradation or an abnormal operation. In another scenario, involving a renewable energy storage system, the battery monitor processing element 121 may leverage data from a charging zone to evaluate the SOH of the battery at the early stage of the charging cycle, enabling proactive maintenance and ensuring optimal performance of the electronic device 100.

In an example, the communicator 130 may perform internal communications between internal hardware components and communicate with an external device (e.g., a server) via one or more networks (e.g., radio technology). The communicator 130 may include an electronic circuit specific to a predetermined standard that enables wired or wireless communication. In an example, the battery 140 may be included with the electronic device 100, providing power for the operation of the electronic device 100. The battery 140 may include, for example, a high-capacity lithium-ion battery with a nominal voltage of 3.7 volts (V) and a capacity of 3,000 milliampere-hour (mAh). The display apparatus 150 (e.g., a user interface) may accept a user input and include a liquid crystal display (LCD), a light-emitting diode (LED) display, an organic light-emitting diode (OLED), or another type of display. The user input may include, but is not limited to, a touch, a swipe, a drag, and a gesture.

A function associated with various components of the electronic device 100 may be performed through a non-volatile memory, a volatile memory, and the processor 120. One or more processors may process input data in accordance with a predefined operating rule or AI model stored in a non-volatile memory and a volatile memory. The predefined operating rule or AI model may be provided through training or learning. Here, being provided through learning may indicate that, by applying a plurality of pieces of learning data, a predefined operating rule or AI model with desired characteristics is generated. Learning may be performed in a device itself in which AI is implemented or may be implemented through a separate server/system. A learning mechanism is a method of training a predetermined target device (e.g., a smartphone) using a plurality of pieces of learning data (e.g., EOL, SOH, etc.) to allow the predetermined target device to decide or predict. Examples of the learning mechanism may include, but are not limited to, supervised learning, unsupervised learning, semi-supervised learning, and reinforcement learning.

In an example, the AI model may include a plurality of neural network layers. Each layer may have multiple weight values and perform a layer operation through a calculation of a previous layer and an operation of multiple weights. Examples of neural networks may include, but are not limited to, a convolutional neural network (CNN), a deep neural network (DNN), a recurrent neural network (RNN), a restricted Boltzmann machine (RBM), a deep belief network (DBN), a bidirectional recurrent deep neural network (BRDNN), a generative adversarial network (GAN), and a deep Q-network.

Although FIG. 1 shows various hardware components of the electronic device 100, it may be understood that other examples are not limited thereto. In other examples, the electronic device 100 may include fewer or more components. Furthermore, labels or names of components are used only for illustrative purposes and do not limit the scope of the present disclosure. One or more components may be combined to perform the same or substantially similar functions to determine the battery performance of the electronic device 100.

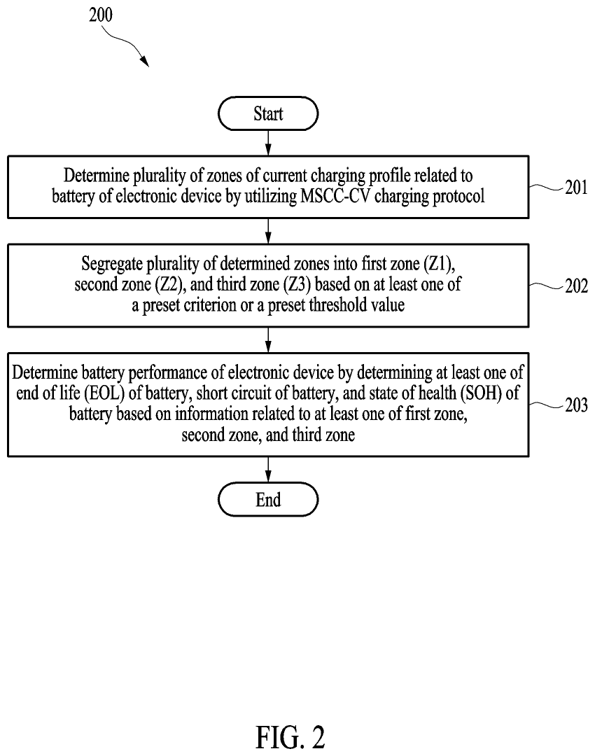

FIG. 2 illustrates an example method 200 of determining battery performance in an electronic device according to one or more embodiments.

Referring to FIG. 2, in a non-limiting example, in method 200, step 201 may determine a plurality of zones associated with a current charging profile of the battery 140 of the electronic device 100 by utilizing an MSCC-CV charging protocol, as described in greater detail below with respect to FIG. 3.

In step 202, the plurality of determined zones may be segregated into a first zone Z1, a second zone Z2, and a third zone Z3, based on one or more of a preset criterion or a preset threshold value, as described below in FIG. 3. In other examples, the plurality of determined zones may be segregated into more than three zones.

In step 203, one or more of the EOL of the battery 140, the short circuit of the battery 140, the SOH of the battery 140 at the early stage of the charging cycle of the battery 140 may be determined based on information related to at least one of the first zone, the second zone, and the third zone, as described in greater detail below with respect to FIGS. 4, 5, 6, 7, 8, and 9.

In addition, a detailed description of various steps of FIG. 2 is provided in the description with reference to FIGS. 4, 5, 6, 7, 8, and 9.

FIG. 3 illustrates an example chart of a scenario 300 in which an electronic device segregates a plurality of zones into a first zone, a second zone, and a third zone, based on a predefined criterion according to one or more embodiments.

In an example, a standard MS-CCCV charging protocol may be utilized to segregate the plurality of zones described with reference to FIG. 3. Referring to FIG. 3, in a non-limiting example, a MS-CCCV charging protocol may include three distinct zones (e.g., zone 1 as the first zone Z1, zone 2 as the second zone Z2, and zone 3 as the third zone Z3), each with predetermined charging current and SOC characteristics.

In the first zone Z1, a charging profile may follow a CC-CV protocol with a charging current of 2.957 A (1.62 C), execute charging until a voltage reaches 4.12 V, and then transition to CV charging at 2.275 A.

In the second zone Z2, the charging profile may follow the CC-CV protocol with a charging current of 2.275 A (1.25 C), execute charging until the voltage reaches 4.22 V, and then transition to CV charging at 1.820 A.

In the third zone Z3, the charging profile may follow the CC-CV protocol with a charging current of 1.820 A (1 C), execute charging until the voltage reaches 4.42 V, and then transition to CV charging at 0.228 A, followed by a 30-minute rest period.

In an example, each zone may be designed to optimize the charging process for different states of the battery 140 to provide efficient and safe charging while maximizing battery life and performance.

FIG. 4 illustrates an example method 400 of determining the EOL of a battery of an electronic device at an early stage of the charging cycle of the battery according to one or more embodiments.

Referring to FIG. 4, in a non-limiting example, in method 400 step 401 may include determining a charge capacity in the first zone Z1. In an example, the charge capacity may be determined using Equation 1 below.

$${Q}_{n} = {\int }_{t 1}^{t 2} Idt \qquad Equation 1$$

Here, Qₙ may denote a charge capacity, t1 may denote a time point at which CC-CV charging starts, and t2 may denote a time point at which the CC-CV charging ends.

In step 402, the EOL of the battery 140 may be determined at the early stage based on a result of the determination of the charge capacity, as described below with reference to FIG. 5.

In an example, an EOL prediction equation may be expressed by Equation 2.

$$γ EOL = 1.81 γ EOL - 1 \qquad Equation 2$$

Here, γEOL-1 may denote a γ value when Q1(γ) reaches 80% of capacity Q1(γ=1-5). This equation may serve as a predictive model for estimating the EOL of the electronic device 100, based on a degradation behavior observed in a previous cycle. The parameter γ may represent a predetermined characteristic or property of the electronic device 100, and Equation 2 may provide a method of estimating an EOL, based on a degradation trend and the threshold value of 80% capacity.

FIG. 5 illustrates an example chart of a scenario 500 in which an electronic device determines the EOL of a battery at an early stage of the charging cycle of the battery according to one or more embodiments.

Referring to FIG. 5, in a non-limiting example, charge capacities within various zones of an MS-CCCV protocol as a function of a cycle number are illustrated, in addition to a discharge capacity of a cell. This example data is generated in a sub-cell of a battery with a capacity of 2.3 Ah at a temperature of 23° C. In FIG. 5, the charge capacity in the first zone Z1 and the second zone Z2 may tend to decrease as the cycle number increases, while the charge capacities in the third zone Z3 may tend to slightly increase. Accordingly, in the example of FIG. 5, a decrease in discharge capacity may be observed.

In an example, the battery monitor processing element 121 may predict the EOL of the battery 140 in advance by monitoring the capacity of the first zone. The EOL may be defined as a time point at which a battery capacity decreases to 80% of an initial/nominal capacity. Referring to the example of FIG. 5, it may be observed that the EOL of the first zone is reached at approximately 236 cycles, while a cell EOL is reached at around 385 cycles. Therefore, the first zone may indicate the cell EOL approximately 150 cycles in advance (i.e., at the early stage of the charging cycle). This is attributed to the high current (>1.5 C) of the first zone at a low SOC level (0% to 30%), which results in very high resistance in a cell. When combined with a high current, a degradation effect is amplified and becomes more apparent.

FIG. 6 illustrates an example method 600 of determining a short circuit of a battery of an electronic device at an early stage of the charging cycle of the battery according to one or more embodiments.

Referring to FIG. 6, in a non-limiting example, in method 600, at step 601a charge capacity in a first zone and a charge capacity in a third zone may be determined. In an example, the charge capacities may be determined with reference to Equation 1.

In step 602, the relative ratio between the charge capacity in the first zone and the charge capacity in the third zone may be determined. In this case, the relative ratio between the charge capacities may be determined with reference to Equation 3.

In step 603, a short resistance based on the determined relative ratio may be determined. The short resistance may be determined with reference to Equation 1, as described with reference to FIG. 7.

In step 604, the determined short resistance may be classified as a soft short resistance or a hard short resistance, based on a predefined threshold value. That is, the determined short resistance may result in a determination of the presence of a hard short or a soft short within the battery.

In step 605, a user of the electronic device 100 may be given a recommendation to perform one or more actions when the hard short is detected. For example, the user may be given a recommendation to perform the one or more action by utilizing the display apparatus 150 (e.g., by displaying a notification message on the screen of the electronic device 100). Examples of the one or more actions may include, but are not limited to, replacing the battery 140. In an example, the recommendation may be an indication of the hard short being provided to the user. The indication may include recommendations related to fixing or solving the hard short.

In an example, a short detection criterion may be expressed by Equation 3 and Equation 4 below.

$${Q}^{′} = 1 - \{ [ Q 1 / Q 3 ] γ / [ Q 1 / Q 3 ] γ = 1 \} < 0 \qquad Equation 3$$

$$Short resistance = f ( {Q}^{′} ) \qquad Equation 4$$

Here, Q′ may denote a parameter determined by comparing the ratio of Q1 to Q3 at a predetermined cycle γ to the ratio at the reference cycle γ=1. The above short detection criterion may enable the detection of the presence of a short circuit by comparing the determined parameter to a predetermined threshold value (less than zero). Additionally, the short resistance may be determined as a function of Q′, as shown in Equation 4. This relationship may define the short resistance as a function of the determined parameter Q′, providing insight into the resistance associated with the detected short circuit. It allows for the quantification and characterization of the short circuit state within the electronic device 100. In an example, Q3 may indicate the n-th zone (e.g., a last zone of the n number of zones).

FIGS. 7A and 7B illustrate example charts of a scenario 700 in which an electronic device determines a short circuit of a battery at an early stage of the charging cycle of the battery according to one or more embodiments.

Referring to FIG. 7A, in a non-limiting example, a ratio of the charge capacity of the first zone to the charge capacity of the third zone within an MS-CCCV protocol is illustrated as a function of a cycle number for a first sub-cell with 2.3 Ah capacity. This data is generated at 23° C. for different short resistances. It may be observed that the charge capacity ratio decreases with a cycle number, indicating degradation and that the capacity of the first zone deteriorates at a faster rate than the capacity of the third zone, as illustrated above with respect to FIG. 5. Additionally, the value of the relative ratio varies when there is a short circuit compared to a no-short circuit (∞Ω) case.

Referring to FIG. 7B, in a non-limiting example, the relative difference in the relative ratio (charge capacity ratio (first zone/third zone)) compared to a healthy case may serve as a clear indicator of the presence of a short circuit, with the magnitude indicating the severity of the short circuit. The percentage difference is ˜15% for a 50Ω short circuit and ˜2% for a 500Ω short circuit, providing a favorable resolution and a detection window. Therefore, a simple expression or look-up table may be constructed to determine the short resistance from this relative charge capacity ratio. The method 600, as discussed above, may be effective due to the accumulation of leakage current associated with the short circuit, resulting in slower charging, with a proportion being more pronounced in a lower-current charging zone (i.e., the third zone in the scenario 700).

FIG. 8 illustrates an example method 800 of determining the SOH of a battery of an electronic device at an early stage of the charging cycle of the battery according to one or more embodiments.

Referring to FIG. 8, in a non-limiting example, in method 800, a charge capacity in a first zone and a charge capacity in a third zone may be determined in step 801. In this case, the charge capacities may be determined with reference to Equation 1.

In step 802, the sum of the charge capacities of the first zone and the third zone may be determined. In this case, the sum of the charge capacities of the first zone and the third zone may be determined with reference to Equation 5.

In step 803, the SOH of the battery 140 may be determined at the early stage, based on the result of the determined sum of the charge capacities, as described below in greater detail with respect to FIG. 9. In this case, the SOH may be determined with reference to Equation 6.

In an example, an aging detection criterion (e.g., SOH) may be expressed by Equation 5 and Equation 6 below.

$$( Q 1 + Q 3 ) ( γ ) < 0.98 * ( Q 1 + Q 3 ) ( γ = 1 - 5 ) \qquad Equation 5$$

$$SOH = [ ( Q 1 + Q 3 ) ( γ ) ] / [ ( Q 1 + Q 3 ) ( γ = 1 - 5 ) ] \qquad Equation 6$$

Here, (Q1+Q3)(γ) may denote a combined capacity of Q1 and Q3 at a predetermined cycle γ, and (Q1+Q3)(γ=1-5) may denote a combined capacity at a reference cycle γ=1-5. The above aging detection criterion may enable detection of the aging of the electronic device 100 by comparing the sum of the charge capacities at a predetermined cycle to a threshold value, based on the sum of the charge capacities at the reference cycle. Equation 6 may provide a quantitative measure of the health (i.e., SOH) of the electronic device 100 by evaluating the sum of the charge capacities at a predetermined cycle relative to the combined capacity at the reference cycle. It offers insight into the overall state and performance of the electronic device 100, allowing the evaluation of aging and degradation over time.

FIG. 9 illustrates an example chart of a scenario 900 in which an electronic device determines the SOH of a battery at an early stage of the charging cycle of the battery according to one or more embodiments.

Referring to FIG. 9, in a non-limiting example, a variation in the SOH is illustrated which may be according to a cycle number, based on the capacities of the first zone and the third zone (these two zones together represent less than 60% of the total SOC), and indicate the actual SOH of a predetermined sub-cell. The data illustrated is FIG. 9 is an example generated at a temperature of 23° C. The SOH calculation, which is based on the capacities in the two charging zones, may effectively capture the variation in the actual SOH, with a maximum error of less than 1%. The method 800 disclosed in the present disclosure may be advantageous in that only available charging data that does not exceed 60% SOC information is required to determine the actual SOH and that a full 100% of the information is not required. While the first zone may show accelerated degradation and detect an EOL, the lost capacity of the first zone may be somewhat regained in the third zone, as the third zone may be a low current charging zone, thereby compensating for the loss. The combination of the first zone and the third zone may be similar to the actual SOH.

The total number of zones may correspond to the number of constant-current constant voltage (CC-CV) steps in an MS-CCCV protocol. In the previously described examples, there are three CC-CV steps, and therefore, it may be divided into three zones. For example, in a charging protocol with “n” CC-CV steps, the total number of zones may be “n”, and the previously mentioned examples may be applicable to estimate an EOL, an SOH, and a short circuit using the first zone and the n-th zone (e.g., the third zone, a fourth zone, and/or a last zone of a plurality of zones).

In an example, instead of the typical EOL determination, the above method may require only first zone data including a high current CC-CV at a low SOC to determine the EOL of the battery 140 before at least 40% of the total cycle. Additionally, the method may require only two data points (the capacity of the first zone and the capacity of the third zone) from available charging data, thereby accurately detecting short circuits, classifying the short circuits, and estimating a short resistance. By considering the ratio and weighted combination of charge capacities in the first zone, which is a low SOC-high current, and the third zone, which is a high SOC-low current, short circuits may be quickly detected as early as 500Ω. Moreover, the sum of these capacities may estimate the SOH within microseconds due to the accumulation of leakage current and its influence on a cell SOC.

In an example, the EOL prediction accuracy from example methods may exceed 90%, as does the accuracy of short circuit detection and estimation. Even very soft short circuits of 500Ω may be detected with over 90% accuracy, while SOH prediction accuracy may be over 99%.

In an example, the above methods do not require special data or probes for multiple assessments of EOL, short circuit detection, and SOH estimations, eliminating the need for device modifications or the use of special probes that involve switching off the electronic device 100 unlike typical EOL assessment methods.

In an example, from a device implementation perspective, no modifications to the existing protocol are necessary. With minimal available user data, multiple safety and health metrics may be evaluated immediately at no computational cost.

The various tasks, actions, blocks, steps, operations, or the like in the flowcharts (e.g., 200, 400, 600, and 800) may be performed in the order presented, in a different order, or simultaneously. Furthermore, in some examples, some of the tasks, actions, blocks, operations, steps, or the like may be omitted, added, modified, skipped, or the like without departing from the scope of the disclosure.

The processors, processing elements, memories, electronic devices, neural networks, electronic device 100, system 101, memory 110, processor 120, battery monitor processing element 121, communicator 130, battery 140, and display apparatus 150 described herein and disclosed herein described with respect to FIGS. 1-9 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
determining a plurality of zones associated with a current charging profile of a battery of an electronic device by utilizing a multi-stage constant-current constant voltage (MSCC-CV) charging protocol;
segregating the determined plurality of zones into a first zone, a second zone, and a third zone, based on a preset criterion; and
determining, based on information associated with one or more of the first zone, the second zone, and the third zone, one or more of an end of life (EOL) of the battery, a short circuit of the battery, and a state of health (SOH) of the battery to determine performance of the battery.

2. The method of claim 1, wherein the first zone comprises a high current-low state of charge (SOC),
wherein the second zone comprises a mid-current-mid SOC, and
wherein the third zone comprises a low current-high SOC.

3. The method of claim 1, wherein the determining of the EOL of the battery comprises:
determining a charge capacity in the first zone; and
determining the EOL of the battery at an early stage of a charging cycle of the battery, based on a result of the determination of the charge capacity.

4. The method of claim 1, wherein the determining of the short circuit of the battery comprises:
determining a first charge capacity in the first zone;
determining a third charge capacity in the third zone;
determining a relative ratio between the first charge capacity and the third charge capacity;
determining a short resistance based on the determined relative ratio; and
classifying the determined short resistance as a soft short resistance or a hard short resistance based on a preset threshold value.

5. The method of claim 4, further comprising:
in response to the determined short resistance being classified as the hard short resistance, providing an indication of the hard short to a user of the electronic device.

6. The method of claim 1, wherein the determining of the SOH of the battery comprises:
determining a first charge capacity in the first zone;
determining a third charge capacity in the third zone;
determining a sum of the charge capacities of the first charge capacity and the third charge capacity; and
determining a charge capacity of the battery at an early stage of a charging cycle of the battery, based on a result of the determined sum.

7. The method of claim 1, wherein the current charging profile of the battery comprises current zone data and a state of charge (SOC) zone.

8. A non-transitory computer-readable storage medium storing instructions that, when executed by at least one processor, cause the at least one processor to perform the method of claim 1.

9. A system, the system comprising:
processors configured to execute instructions; and
a memory storing the instructions, wherein execution of the instructions configures the processors to:
determine a plurality of zones associated with a current charging profile of a battery associated with the system by utilizing a multi-stage constant-current constant voltage (MSCC-CV) charging protocol;
segregate the determined plurality of zones into a first zone, a second zone, and a third zone, based on a preset criterion; and
determine, based on information associated with one or more of the first zone, the second zone, and the third zone, one or more of an end of life (EOL) of the battery, a short circuit of the battery, and a state of health (SOH) of the battery to determine performance of the battery.

10. The system of claim 9, wherein the first zone comprises a high current-low state of charge (SOC),
wherein the second zone comprises a mid-current-mid SOC, and
wherein the third zone comprises a low current-high SOC.

11. The system of claim 9, wherein, to determine the EOL of the battery, the processors are further configured to:
determine a charge capacity in the first zone; and
determine the EOL of the battery at an early stage of a charging cycle of the battery, based on a result of the determination of the charge capacity.

12. The system of claim 9, wherein, to determine the short circuit of the battery, the processors are further configured to:
determine a first charge capacity in the first zone;
determine a third charge capacity in the third zone;
determine a relative ratio between the first charge capacity and the third charge capacity; and
determine a presence of a soft short resistance or a hard short resistance based on the relative ratio compared to a preset threshold value.

13. The system of claim 12, wherein the processors are further configured to:
in response to the determined short resistance being classified as the hard short resistance, notifying a user of the system to perform an action to enhance the performance of the battery.

14. The system of claim 9, wherein the determination of the SOH of the battery comprises:
determining a first charge capacity in the first zone;
determining a third charge capacity in the third zone;
determining a sum of the charge capacities of the first charge capacity and the third charge capacity; and
determining a charge capacity of the battery at an early stage of a charging cycle of the battery, based on a result of the determined sum.

15. The system of claim 9, wherein a current charging profile of the battery comprises current zone data and a state of charge (SOC) zone.

16. An electronic device, comprising:
processors configured to execute instructions; and
a memory storing the instructions, wherein execution of the instructions configures the processors to:
determine a first zone and a plurality of other zones associated with a current charging profile of a battery by utilizing a multi-stage constant-current constant voltage (MSCC-CV) charging protocol based on a preset criterion; and
determine, based on information associated with the first zone and the plurality of other zones, a battery performance of the battery at an early stage of a charging cycle of the battery.

17. The electronic device of claim 16, wherein the battery performance includes one or more of an end of life (EOL) of the battery, a short circuit of the battery, and a state of health (SOH) of the battery.

18. The electronic device of claim 16, wherein the determining of the battery performance comprises:
determining a charge capacity in the first zone; and
determining an end of life (EOL) of the battery based on a result of the determination of the charge capacity.

19. The electronic device of claim 16, wherein the determining of battery performance comprises:
determining a first charge capacity in the first zone;
determining a final charge capacity in a final zone of the plurality of other zones; and
determining whether a hard short or a soft short has occurred within the battery based a relative ratio between the first charge capacity and the final charge capacity being compared against a preset threshold value.
